(19) United States
(12) Patent Application Publication
(10) Pub. No.: US 2016/0302333 A1
(43) Pub. Date: Oct. 13, 2016

(54) ELECTRONIC DEVICE

(71) Applicant: Panasonic Intellectual Property Management Co., Ltd., Osaka (JP)

(72) Inventors: Masato TOBINAGA, Hyogo (JP); Hirotsugu FUSAYASU, Kyoto (JP)

(21) Appl. No.: 15/186,673

(22) Filed: Jun. 20, 2016

Related U.S. Application Data
(63) Continuation of application No. PCT/JP2014/005652, filed on Nov. 11, 2014.

(30) Foreign Application Priority Data
Mar. 18, 2014 (JP) 2014-054647

(51) Int. Cl. H05K 9/00

(52) U.S. Cl. CPC H05K 9/0067

(57) ABSTRACT

Provided is an electronic device with measures to reduce an influence caused by ESD. The electronic device of the present disclosure is provided with a display module, a metal frame holding the display module, a printed circuit board having ground electrically connected to the metal frame, the printed circuit board being equipped with an electronic circuit and being disposed on a surface of the metal frame, the surface being opposite to a surface holding the display module, and a static electricity reducing filter including a dielectric, the static electricity reducing filter being disposed on the surface of the metal frame on which the printed circuit board is disposed. The static electricity reducing filter propagates a predetermined electromagnetic wave in generated electrostatic current to the dielectric.

### BACKGROUND

1. Technical Field

The present disclosure relates to an electronic device with measures to reduce an influence caused by electrostatic discharge (ESD).

2. Description of Related Art

Conventionally, ESD has been a big factor causing operation failures of electronic devices and disconnection of networks. Electronic device manufacturers have been required to take appropriate measures against ESD in design of devices.

As measures against ESD, for example, Unexamined Japanese Patent Publication No. 4-157799 discloses a structure of a casing which houses an electrical appliance circuit, an electrical device, or the like. The casing includes a low resistance conductor which is connected to frame ground. A surface of the casing is formed of a high resistance conductor. An insulator is interposed between the high resistance conductor and the low resistance conductor on an inner face. The high resistance conductor is connected to the frame ground.

### SUMMARY

The present disclosure provides an electronic device with measures to reduce the influence caused by ESD.

The electronic device of the present disclosure is provided with a display module, a metal frame holding the display module, a printed circuit board having ground electrically connected to the metal frame, the printed circuit board being equipped with an electronic circuit and being disposed on a surface of the metal frame, the surface being opposite to a surface holding the display module, and a static electricity reducing filter including a dielectric, the static electricity reducing filter being disposed on the surface of the metal frame on which the printed circuit board is disposed. The static electricity reducing filter propagates a predetermined electromagnetic wave in generated electrostatic current to the dielectric.

The electronic device in the present disclosure is capable of reducing the influence caused by ESD. In particular, the present disclosure is effective in reducing the influence caused by ESD in tablet electronic devices (hereinbelow, merely referred to as “tablets”) with slim bodies and large screens.

### BRIEF DESCRIPTION OF DRAWINGS

FIG. 1 is a sectional view of a conventional tablet.

FIG. 2 is a graph illustrating a relationship between a tablet size and a capacitance ratio.

FIG. 3 is an exploded perspective view of a tablet according to a first exemplary embodiment.

FIG. 4 is a sectional view taken along line 4-4 of FIG. 3.

FIG. 5 is a view in direction A of FIG. 4.

FIG. 6 is a diagram describing a propagation operation of electrostatic current flowing through a metal frame and electrostatic current flowing through a static electricity reducing filter in the first exemplary embodiment.

FIG. 7 is a diagram illustrating propagation of electrostatic current in the metal frame and propagation of electrostatic current inside a dielectric in the first exemplary embodiment.

FIG. 8 is a diagram illustrating changes with time of electrostatic currents at point B of FIG. 6.

FIG. 9A is a characteristic diagram illustrating a test waveform of an electrostatic gun defined in IEC61000-4-2.

FIG. 9B is a characteristic diagram illustrating a waveform obtained by Fourier transforming the test waveform of FIG. 9A.

FIG. 10A is a diagram illustrating a result of analysis of electrostatic current distribution on a conventional tablet.

FIG. 10B is a diagram illustrating a result of analysis of electrostatic current distribution on the tablet of the first exemplary embodiment.

FIG. 11 is a sectional view of a tablet of a second exemplary embodiment.

FIG. 12 is a diagram in direction A of FIG. 11.

FIG. 13 is a diagram describing a propagation operation of electrostatic current flowing through a metal frame and electrostatic current flowing through a static electricity reducing filter in the second exemplary embodiment.

### DESCRIPTION

Hereinbelow, exemplary embodiments will be described in detail with reference to the drawings in an appropriate manner. However, unnecessarily detailed description may be omitted. For example, detailed description of an already well-known matter and overlapping description of substantially the same configurations may be omitted in order to avoid the following description from becoming unnecessarily redundant and to make it easy for a person skilled in the art to understand the following description.

The accompanying drawings and the following description are provided so that a person skilled in the art can sufficiently understand the present disclosure. Therefore, the accompanying drawings and the following description are not intended to limit the subject matter defined in the claims.

### First Exemplary Embodiment

### 1-1. Problems

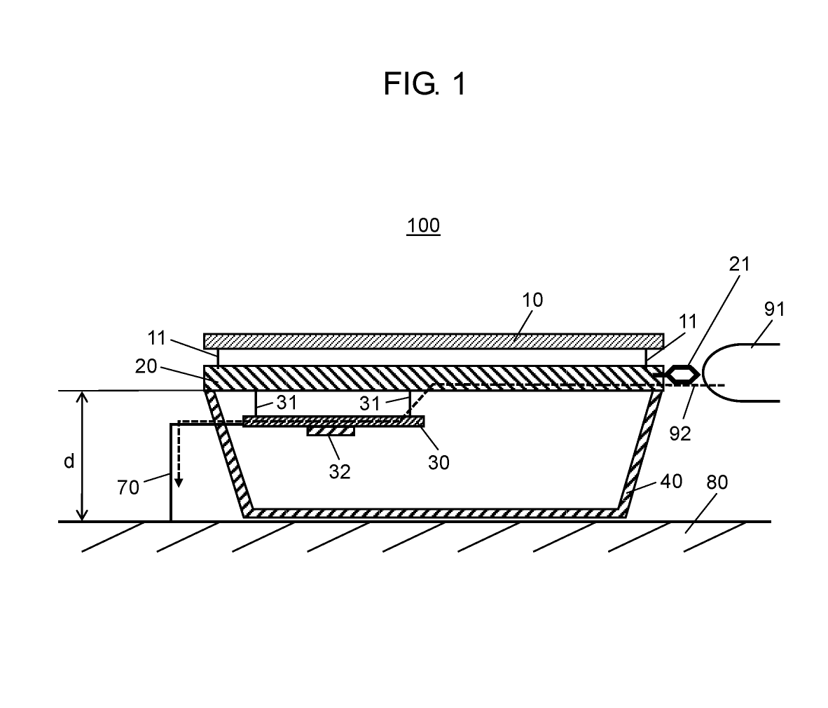

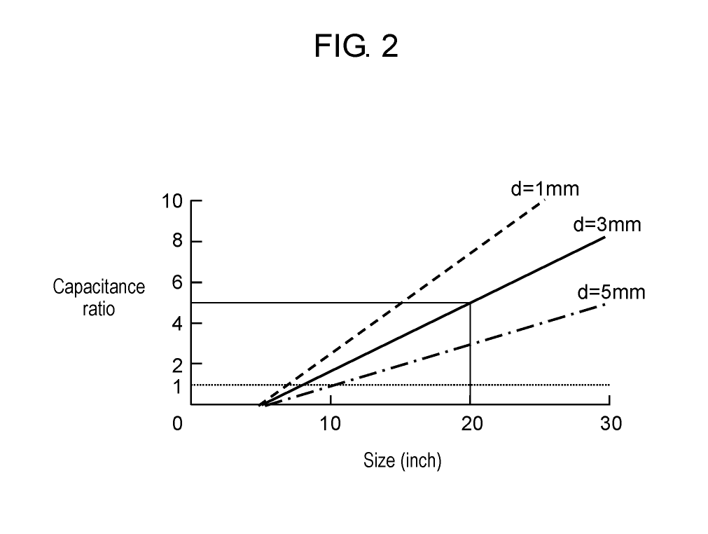

First, problems caused by ESD in a large-screen tablet will be described with reference to FIGS. 1 and 2. FIG. 1 is a sectional view of a conventional tablet. FIG. 2 is a graph illustrating a relationship between a tablet size and a capacitance ratio.

In mobile electronic devices including tablets, for example, when a user touches an electronic device, electrostatic current may flow from a casing into a printed circuit board inside the electronic device by ESD to change a potential between a power source and ground of the printed circuit board. This may cause malfunction such as reset of an LSI (Large Scale Integration) mounted on the printed circuit board and a flicker on a screen of an LCD (Liquid Crystal Display) panel of the tablet.

In FIG. 1, tablet 100 includes display module 10 which includes an LCD panel and a driving circuit for the LCD panel, metal frame 20 which is made of magnesium, security hook 21 which is made of stainless steel and connected to metal frame 20 and to which an antitheft wire is attached, printed circuit board 30 which is equipped with LSI 32 as an electronic circuit used in tablet 100 and includes a glass epoxy substrate, and resin sheath 40 which houses printed circuit board 30 therein.

Display module 10 and metal frame 20 are connected through connection part 11. Printed circuit board 30 and metal frame 20 are connected through connection part 31 which is a conductive member. Ground of printed circuit board 30 is electrically connected to metal frame 20.

Tablet 100 has a built-in secondary battery (not illustrated) which includes, for example, a lithium ion battery. Tablet 100 is provided with power cable 70 for charging the secondary battery or for operating tablet 100 from an external power source.

In FIG. 1, tablet 100 is placed on metal table 80. In FIG. 1, d denotes a distance between metal frame 20 and metal table 80. ESD becomes remarkable when tablet 100 is used on a conductive material such as metal table 80. Metal frame 20 of tablet 100 is made of a conductive material, specifically, magnesium. Thus, when tablet 100 is used on metal table 80, a large stray capacitance is formed between tablet 100 and metal table 80, which causes a low impedance state and increases electrostatic current.

In tablet 100, touching security hook 21 which is a conductive member, specifically, stainless steel connected to metal frame 20 with finger 91 generates static electricity 92. Electrostatic current 92 thus generated flows to metal frame 20, flows to printed circuit board 30 through connection part 31, passes through power cable 70, and flows to the ground. Since electrostatic current 92 flows through printed circuit board 30, electrostatic current 92 also flows through LSI 32 mounted on printed circuit board 30. An increase in electrostatic current 92 flowing through LSI 32 causes LSI 32 to malfunction.

In FIG. 2, a horizontal axis represents a size of the LCD panel of display module 10 in tablet 100 and a vertical axis represents a capacitance ratio relative to a reference. A capacitance generated when the size of the LCD panel is 10 inches and distance d between metal frame 20 and metal table 80 is 5 mm is defined as 1 as the reference. FIG. 2 illustrates the size of the LCD panel and the capacitance ratio relative to the reference when distance d is 1 mm, 3 mm, and 5 mm.

Electrostatic current I and capacitance C formed between metal table 80 and metal frame 20 satisfy a relation of I=jωCV, where ω denotes a frequency and V denotes a voltage. Further, capacitance C, and facing area S and distance d between metal table 80 and metal frame 20 satisfy C=ε0(S/d), where ε0 denotes a dielectric constant of air. That is, I∝(S/d) is satisfied. As facing area S increases, that is, the size of the LCD panel increases and distance d decreases, that is, as tablet 100 is enlarged and slimmed down, electrostatic current I increases. In FIG. 2, for example, when the size is 20 inches and distance d is 3 mm, the capacitance is approximately five times as large as the reference.

In this manner, along with an enlargement in the size of tablet 100 to 20 inches or more and a further slimming down of tablet 100 for, for example, electric/machinery design purposes or education purposes, an amount of electrostatic current flowing into LSI 32 increases to cause malfunction. As a result, problems caused by static electricity become more serious.

Regarding ESD, immunity requirements and a test method in an electronic device for ESD generated directly from a charged operator or from an adjacent object is defined in IEC61000-4-2 set by IEC (International Electrotechnical Commission). Static electricity is applied to an electronic device from an electrostatic gun as an ESD generator which simulates a phenomenon of electric charges accumulated on an operator discharging toward an electronic device under a low humidity environment or a condition of using chemical fiber carpets or clothes. Tablet 100 is required to pass the test defined in IEC61000-4-2.

### 1-2. Configuration

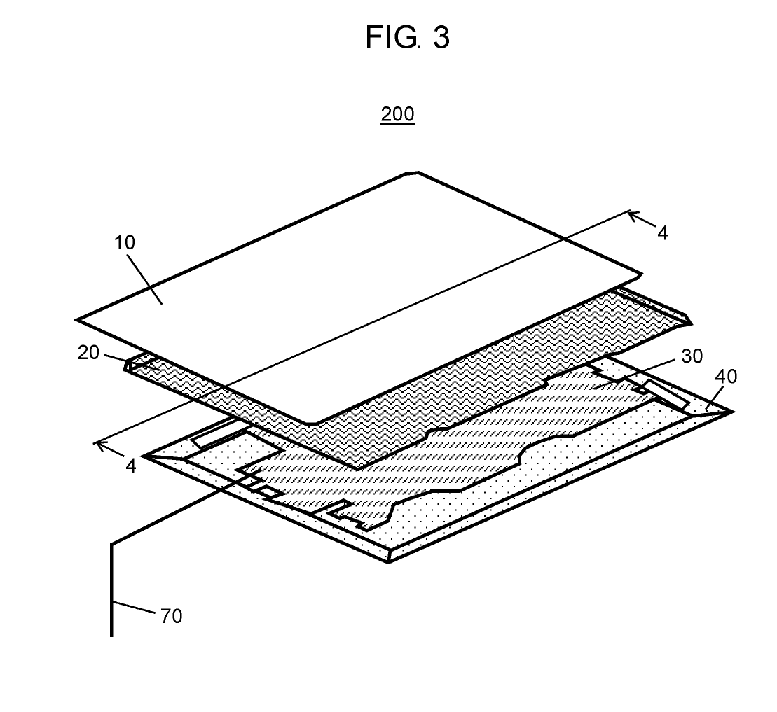

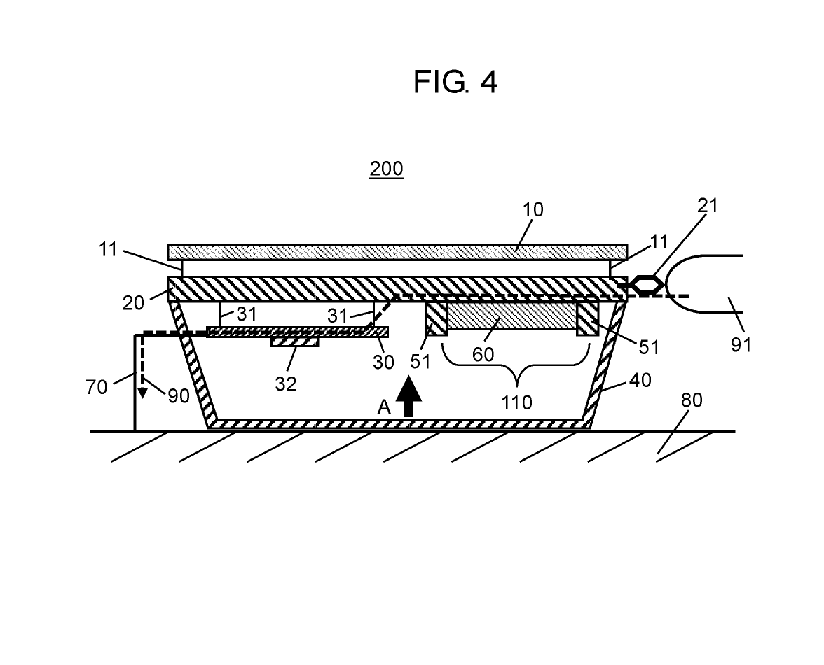

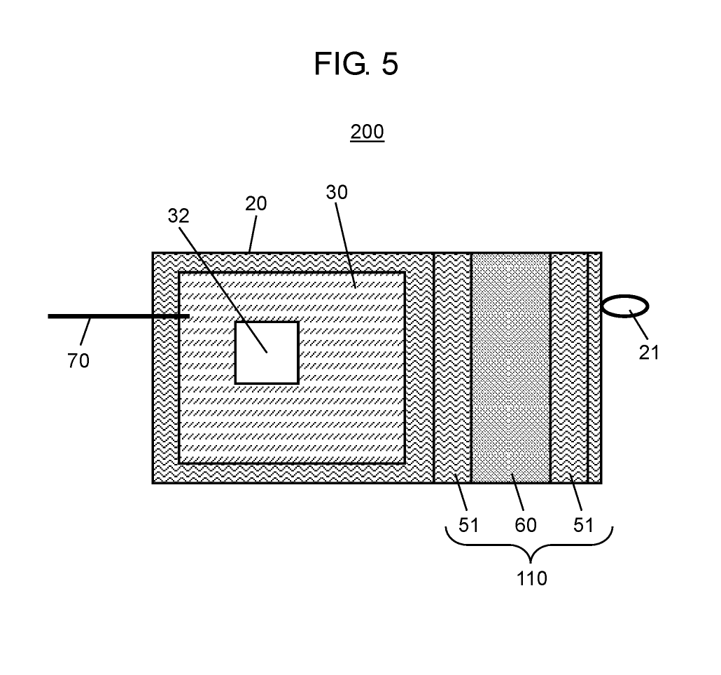

FIG. 3 is an exploded perspective view of a tablet according to the first exemplary embodiment. FIG. 4 is a sectional view taken along line 4-4 of FIG. 3. FIG. 5 is a view in direction A of FIG. 4.

Tablet 200 is provided with static electricity reducing filter 110 in addition to the configuration of tablet 100. An LCD panel in display module 10 of tablet 200 is 20 inches in size and 5 mm in thickness.

Tablet 200 includes display module 10 which includes the LCD panel and a driving circuit for the LCD panel, metal frame 20 which is made of magnesium, security hook 21 which is made of stainless steel and connected to metal frame 20 and to which an antitheft wire is attached, printed circuit board 30 which is equipped with LSI 32 as an electronic circuit used in tablet 200 and includes a glass epoxy substrate, and resin sheath 40 which houses printed circuit board 30 therein. Metal frame 20 is provided with static electricity reducing filter 110 (described below).

In FIG. 4, tablet 200 is placed on metal table 80.

Metal frame 20 includes a conductive flat plate having a rectangular shape of 480 mm in lateral length and 340 mm in width. Display module 10 and metal frame 20 are connected through connection part 11. Printed circuit board 30 and metal frame 20 are connected through connection part 31 which is a conductive member. Ground of printed circuit board 30 is electrically connected to metal frame 20.

Tablet 200 has a built-in secondary battery (not illustrated) which includes, for example, a lithium ion battery. Tablet 200 is provided with, for example, detachable power cable 70 for charging the secondary battery or for operating tablet 200 from an external power source.

Tablet 200 is provided with static electricity reducing filter 110. Static electricity reducing filter 110 includes dielectric 60 which is filled in a groove formed by two projections 51 which are made of magnesium and disposed on metal frame 20. Two projections 51 are made of the same material as metal frame 20. Two projections 51 are formed by pressing metal frame 20. As illustrated in FIG. 5, static electricity reducing filter 110 is formed on metal frame 20 in a short-side direction of metal frame 20 at a side near security hook 21. Dielectric 60 plays a role of shortening a wavelength as a propagation distance of electrostatic current passing through static electricity reducing filter 110, that is, reducing a propagation velocity by a dielectric constant of dielectric 60. Dielectric 60 is composed of polyimide. As a material of dielectric 60, materials such as glass having a dielectric constant of 5.2 and polyester having a dielectric constant of 8 are used.

Although the groove in static electricity reducing filter 110 is formed by the two projections, the groove is not limited to this configuration. For example, a depression may be formed on metal frame 20. The depression may be formed by pressing metal frame 20.

Static electricity reducing filter 110 shortens the propagation distance of a predetermined electromagnetic wave among a plurality of electromagnetic waves of electrostatic current (described below) to set a difference between a phase of electrostatic current flowing through a surface of metal frame 20 at a predetermined position and a phase of electrostatic current flowing through dielectric 60 at the predetermined position to π radian (180°). This configuration enables electrostatic current to be reduced.

### 1-3. Operation

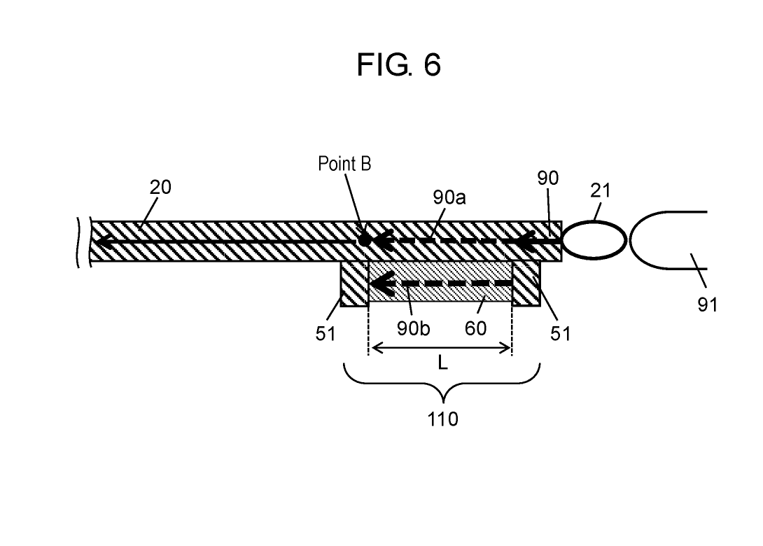

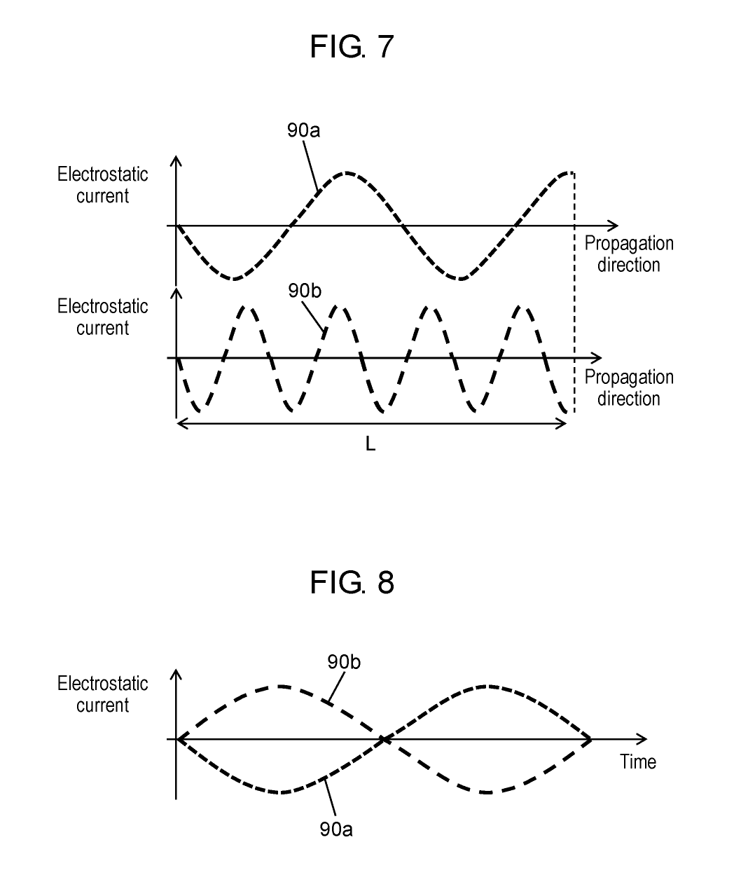

Next, a propagation operation of electrostatic current flowing through tablet 200 will be described. FIG. 6 is a diagram describing the propagation operation of electrostatic current flowing through metal frame 20 and electrostatic current flowing through static electricity reducing filter 110. FIG. 7 is a diagram illustrating propagation of electrostatic current in metal frame 20 and propagation of electrostatic current inside dielectric 60. FIG. 8 is a diagram illustrating changes with time of electrostatic currents at point B of FIG. 6.

In FIG. 6, touching security hook 21 with finger 91 generates static electricity. Electrostatic current 90 flowing through metal frame 20 is divided into electrostatic current 90a flowing through metal frame 20 and electrostatic current 90b flowing through dielectric 60. An electrical path difference between electrostatic current 90a flowing through metal frame 20 and electrostatic current 90b flowing through dielectric 60 is generated, and length L of dielectric 60 is determined so that the phase difference is π radian (180°) at a specific frequency.

An upper graph of FIG. 7 illustrates a change of electrostatic current 90a flowing through metal frame 20 with respect to a propagation direction.

A lower graph of FIG. 7 illustrates a change of electrostatic current 90b flowing through dielectric 60 with respect to a propagation direction. FIG. 8 illustrates a change with time of electrostatic current 90a and a change with time of electrostatic current 90b at point B.

When length L of dielectric 60 is determined in the above manner, as illustrated in FIGS. 7 and 8, electrostatic current 90b passing through dielectric 60 and electrostatic current 90a are out of phase by 180° and cancel each other at point B which is an end of dielectric 60, the end facing printed circuit board 30. Thus, an intensity of the electrostatic current 90 reaching printed circuit board 30 decreases, which enables malfunction of the electronic device to be reduced.

As described above, static electricity reducing filter 110 of tablet 200 cancels electrostatic current flowing through metal frame 20 and electrostatic current flowing through dielectric 60. This enables electrostatic current to be reduced.

Next, a method for calculating length L of dielectric 60 will be described.

Length L of dielectric 60 is determined so that the phase difference between electrostatic current 90a and electrostatic current 90b is π radian. A phase advancing in a propagation path of electrostatic current 90a is 2 πL/λ and a phase advancing in a propagation path of electrostatic current 90b is 2 πεL/λ, where λ denotes a wavelength transmitting in a space and ε denotes the dielectric constant of dielectric 60. In order to set the phase difference between electrostatic current 90a and electrostatic current 90b to π radian, (2 πεL/λ)−(2 πL/λ)=π should be satisfied. Since λ=c/f is satisfied, where c denotes a phase velocity of an electromagnetic wave and f denotes a frequency, L=λ/2 (ε−1)=c/{2 f (ε−1)} is satisfied. When glass having a dielectric constant of, for example, 7 is used as dielectric 60, f=200 MHz, and c=300 Mm/s, length L of dielectric 60 is 125 mm.

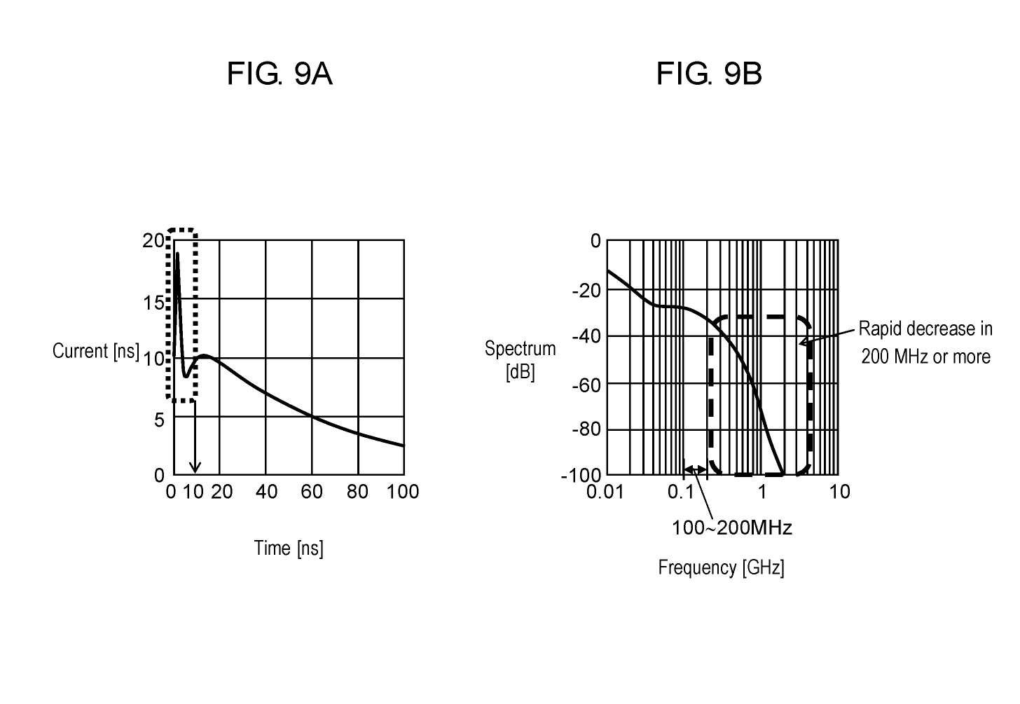

Next, a band of the static electricity reduction will be described with reference to FIGS. 9A and 9B. Tablet 200 is required to pass the test defined in IEC61000-4-2. FIG. 9A is a characteristic diagram illustrating a test waveform of an electrostatic gun defined in IEC61000-4-2. FIG. 9B is a characteristic diagram illustrating a waveform obtained by Fourier transforming the test waveform of FIG. 9A. In FIG. 9A, a horizontal axis represents time and a vertical axis represents the test waveform as electrostatic current. In FIG. 9B, a horizontal axis represents frequency and a vertical axis represents a frequency spectrum waveform of electrostatic current as a spectrum.

The test waveform in FIG. 9A has a particularly large current value between start of the test and an elapsed time 10 ns. Thus, reducing amplitude in this part is effective for measures against static electricity. In FIG. 9B, a frequency component is 100 MHz or less between the start of the test and the elapsed time 10 ns in FIG. 9A. Thus, a component of 100 MHz or more is effective to reduce a peak of electrostatic current.

In FIG. 9B, a spectrum intensity rapidly decreases when the frequency is 200 MHz or more. This shows that a component of 200 MHz or less is large.

As described above, it is effective to perform static electricity reducing measures on electromagnet waves with a frequency ranging from 100 MHz to 200 MHz inclusive in which the frequency spectrum intensity of electrostatic current becomes a predetermined value or more.

Thus, in static electricity reducing filter 110, length L of dielectric 60 is determined so that the difference between the phase of electrostatic current flowing through the surface of metal frame 20 at point B and the phase of electrostatic current flowing through dielectric 60 at point B is π radian with respect to a predetermined electromagnet wave among electromagnet waves with a frequency ranging from 100 MHz to 200 MHz inclusive in which the frequency spectrum intensity of electrostatic current becomes the predetermined value or more. When glass having a dielectric constant of 7 is used as dielectric 60, length L ranges from 125 mm to 250 mm inclusive. A range of length L of dielectric 60 is a settable length with respect to the length of the long side in metal frame 20, specifically, 480 mm.

The frequency of electrostatic current is targeted from 100 MHz to 200 MHz inclusive. Thus, electrostatic current flows near the surface of metal frame 20. Although FIG. 6 illustrates electrostatic current 90a flowing near a center of metal frame 20 and electrostatic current 90b flowing near a center of dielectric 60, electrostatic current 90a and electrostatic current 90b actually flow near a boundary between metal frame 20 and dielectric 60.

### 1-4. Effect

An analysis of electrostatic current distribution was performed on tablet 100 and tablet 200. The analysis was performed by calculating magnetic field distribution obtained when static electricity is applied to security hook 21 of each of tablets 100 and 200 by a FDTD method (Finite-Difference Time-Domain Method) which is one method of an electromagnetic field analysis. A space was divided into approximately 8.6 million lattices and the calculation was performed for 15 ns in total including approximately 120, 000 steps at every time of approximately 0.247 ps. A model of an electrostatic gun was charged so as to have a charge of 8 kV up to 6 ns and discharged after 6 ns to apply static electricity to tablets 100 and 200 as analysis targets.

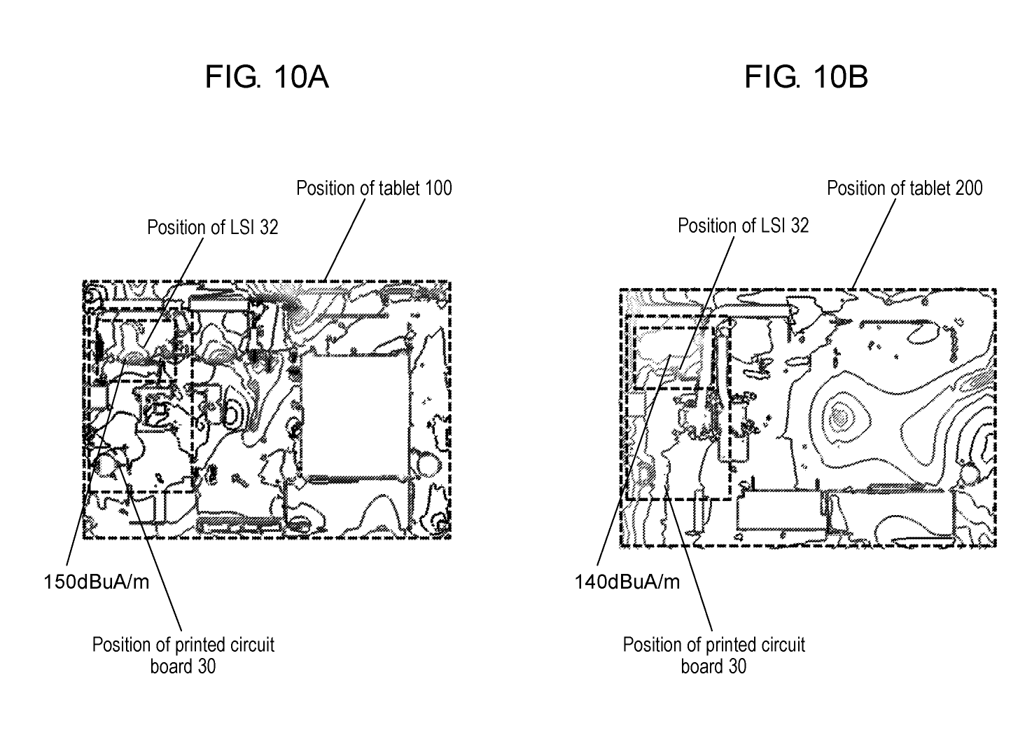

FIG. 10A is a diagram illustrating a result of the analysis of electrostatic current distribution in tablet 100 which is provided with no static electricity reducing filter 110. FIG. 10B is a diagram illustrating a result of the analysis of electrostatic current distribution in tablet 200 which is provided with static electricity reducing filter 110. FIG. 10A shows that static electricity is applied to tablet 100 from a right side in the drawing, so that an electrostatic current generating a magnetic field of 150 dBμA/m in maximum flows at a position of LSI 32 mounted on printed circuit board 30. FIG. 10B shows that static electricity is applied to tablet 200 from a right side in the drawing, so that an electrostatic current generating a magnetic field of 140 dBμA/m in maximum flows at a position of LSI 32 mounted on printed circuit board 30. Thus, in tablet 200 provided with static electricity reducing filter 110, an electrostatic current generating a magnetic field of 10 dBμA/m on LSI 32 is reduced as compared to tablet 100 which is provided with no static electricity reducing filter 110.

As described above, the tablet of the present exemplary embodiment is provided with display module 10, metal frame 20 which holds display module 10, printed circuit board 30 which has ground electrically connected to metal frame 20, is equipped with LSI 32 as an electronic circuit, and is disposed on a surface of metal frame 20, the surface being opposite to a surface holding display module 10, and static electricity reducing filter 110 which includes dielectric 60 and is disposed on the surface of metal frame 20 on which printed circuit board 30 is disposed. Static electricity reducing filter 110 propagates a predetermined electromagnetic wave in generated electrostatic current to dielectric 60.

This configuration enables tablet 200 to reduce the influence caused by ESD merely by disposing static electricity reducing filter 110 on metal frame 20 without adding a structure for reducing static electricity to printed circuit board 30 or LSI 32.

### Second Exemplary Embodiment

Next, a second exemplary embodiment will be described. In the first exemplary embodiment, the static electricity reducing filter includes a single dielectric. On the other hand, in the second exemplary embodiment, a case in which a static electricity reducing filter includes a plurality of dielectrics will be described. Identical reference sings designate configurations similar to the configurations in the first exemplary embodiment.

### 2-1. Configuration

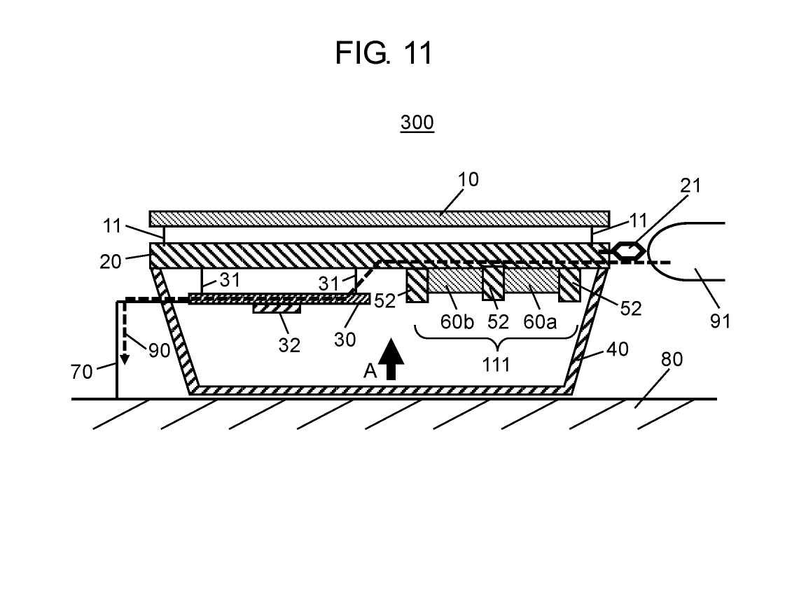

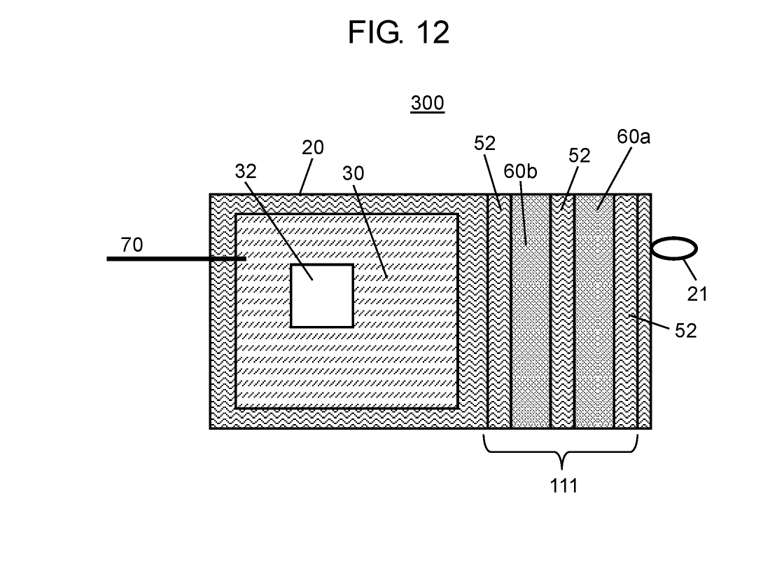

FIG. 11 is a sectional view of tablet 300 of the second exemplary embodiment. FIG. 12 is a diagram in direction A of FIG. 11.

Tablet 300 is provided with static electricity reducing filter 111. Static electricity reducing filter 111 includes first dielectric 60a and second dielectric 60b which are filled in two grooves formed by three projections 52 which are made of magnesium and disposed on metal frame 20. Three projections 52 are formed by pressing metal frame 20. The present exemplary embodiment differs from the first exemplary embodiment in that static electricity reducing filter 111 includes first dielectric 60a and second dielectric 60b which are filled in the two grooves.

Metal frame 20 includes a conductive flat plate having a rectangular shape of 480 mm in lateral length and 340 mm in width. First dielectric 60a and second dielectric 60b play a role of shortening a wavelength as a propagation distance of electrostatic current passing through static electricity reducing filter 111, that is, reducing a propagation velocity by dielectric constants of first dielectric 60a and second dielectric 60b. First dielectric 60a and second dielectric 60b are both composed of polyimide. Materials such as glass having a dielectric constant of 5.2 and polyester having a dielectric constant of 8 are used as first dielectric 60a and second dielectric 60b.

Although the grooves in static electricity reducing filter 111 are formed by the three projections, the grooves are not limited to this configuration. For example, two depressions may be formed on metal frame 20. The depressions may be formed by pressing metal frame 20.

### 2-2. Operation

Next, a propagation operation of electrostatic current flowing through tablet 300 will be described.

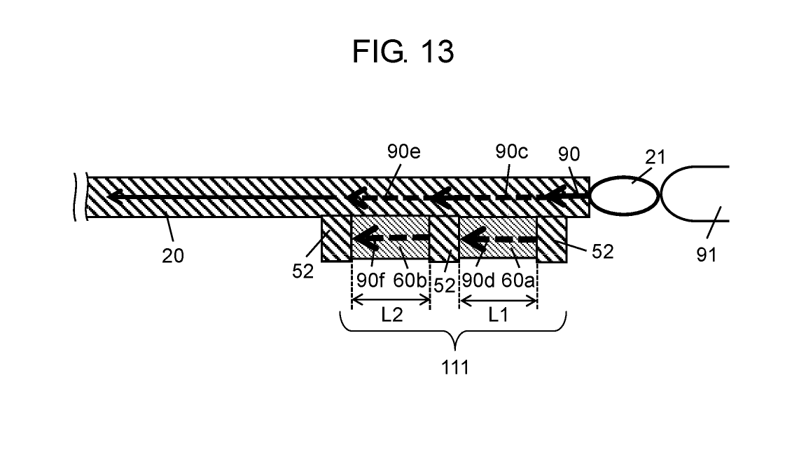

FIG. 13 is a diagram describing the propagation operation of electrostatic current flowing through metal frame 20 and electrostatic current flowing through static electricity reducing filter 111. In FIG. 13, touching security hook 21 with finger 91 generates static electricity. Electrostatic current 90 flowing through metal frame 20 is divided into electrostatic current 90c flowing through metal frame 20 and electrostatic current 90d flowing through first dielectric 60a. An electrical path difference between electrostatic current 90c flowing through metal frame 20 and electrostatic current 90d flowing through first dielectric 60a is generated, and length L1 of first dielectric 60a is determined so that a phase difference is π radian (180°) at a specific frequency. Accordingly, electrostatic current 90c and electrostatic current 90d passing through first dielectric 60a are out of phase by 180° and cancel each other. As a result, an intensity of electrostatic current reaching printed circuit board 30 decreases. Further, electrostatic current 90c flowing through metal frame 20 is divided into electrostatic current 90e flowing through metal frame 20 and electrostatic current 90f flowing through second dielectric 60b. An electrical path difference between electrostatic current 90e flowing through metal frame 20 and electrostatic current 90f flowing through second dielectric 60b is generated, and length L2 of second dielectric 60b is determined so that a phase difference is π radian (180°) at a specific frequency. Accordingly, electrostatic current 90e flowing through metal frame 20 and electrostatic current 90f passing through second dielectric 60b are out of phase by 180° and cancel each other. As a result, the intensity of electrostatic current reaching printed circuit board 30 decreases.

As described above, the configuration of static electricity reducing filter 111 including the two dielectrics doubly cancels electrostatic current flowing through metal frame 20 and electrostatic current flowing through first dielectric 60a and second dielectric 60b. Accordingly, static electricity reducing measures are performed.

Length L1 of first dielectric 60a and length L2 of second dielectric 60b may differ from each other. For example, when glass having a dielectric constant of 7 and having a width of 125 mm is used as first dielectric 60a and glass having a dielectric constant of 7 and having a width of 250 mm is used as second dielectric 60b, static electricity can be reduced respectively on 200 MHz and 100 MHz.

### 2-3. Effect

As described above, tablet 300 of the present exemplary embodiment is provided with display module 10, metal frame 20 which holds display module 10, printed circuit board 30 which has ground electrically connected to metal frame 20, is equipped with LSI 32 as an electronic circuit, and is disposed on a surface of metal frame 20, the surface being opposite to a surface holding display module 10, and static electricity reducing filter 111 which includes first dielectric 60a and second dielectric 60b as a plurality of dielectrics and is disposed on the surface of metal frame 20 on which printed circuit board 30 is disposed. Static electricity reducing filter 111 propagates a predetermined electromagnetic wave in generated electrostatic current to first dielectric 60a and second dielectric 60b as a plurality of dielectrics. Further, first dielectric 60a and second dielectric 60b as a plurality of dielectrics are disposed in tandem along a propagation direction of electrostatic current.

Accordingly, tablet 300 which uses static electricity reducing filter 111 includes the two dielectrics. Thus, a further effect for reducing electrostatic current can be obtained for a large screen tablet having a screen of 20 inches or more.

Although, in the second exemplary embodiment, the static electricity reducing filter includes two dielectrics, the static electricity reducing filter may include three or more dielectrics. In the configuration provided with a plurality of dielectrics, appropriately selecting a material and a length of each of the dielectrics makes it possible to further expand a frequency band having a static electricity reducing effect or further reduce electrostatic current in the same frequency band.

Although, in the first and second exemplary embodiments, the phase difference between electrostatic current flowing through the metal frame and electrostatic current flowing through the static electricity reducing filter is 180°, the phase difference is not limited to 180°. Any phase difference may be employed as long as a static electricity reducing effect can be exhibited.

Although, in the first and second exemplary embodiments, static electricity is generated by touching the security hook with the finger, the generation of static electricity is not limited to this configuration. Static electricity may be generated when a charged user touches a conductive member projecting on a sheath of the tablet or a conductive member inside a hole formed on the sheath directly or through an adjacent object.

Although, in the first and second exemplary embodiments, the power cable is connected to the tablet, a charged secondary battery may be used without connecting the tablet to the power cable.

The present disclosure is applicable to tablet electronic devices that can be used on a metal table. Specifically, the present disclosure is applicable to, for example, tablets and smartphones as tablet electronic devices.

What is claimed is:

1. An electronic device comprising:
a display module;
a metal frame holding the display module;
a printed circuit board having ground electrically connected to the metal frame, the printed circuit board being equipped with an electronic circuit and being disposed on a surface of the metal frame, the surface being opposite to a surface holding the display module;
a groove formed on the surface of the metal frame on which the printed circuit board is disposed; and
a static electricity reducing filter disposed in the groove, the static electricity reducing filter including a dielectric,
wherein the static electricity reducing filter propagates a predetermined electromagnetic wave in generated electrostatic current to the dielectric.

2. The electronic device according to claim 1, wherein the static electricity reducing filter provides a phase difference between a phase of electrostatic current flowing through the metal frame and a phase of electrostatic current flowing through the dielectric at a predetermined position.

3. The electronic device according to claim 2, wherein the phase difference is 180°.

4. The electronic device according to claim 1, wherein the predetermined electromagnetic wave ranges from 100 MHz to 200 MHz inclusive.

5. The electronic device according to claim 1,
wherein the static electricity reducing filter includes a plurality of dielectrics, and
wherein the dielectrics are disposed in tandem along a propagation direction of electrostatic current.

6. The electronic device according to claim 5, wherein at least two of the dielectrics have different dielectric constants.

7. The electronic device according to claim 1, wherein the groove is formed by a projection disposed on the metal frame.
